(19) United States
(12) Patent Application Publication
(10) Pub. No.: US 2025/0098359 A1
(43) Pub. Date: Mar. 20, 2025

(54) SILICON WAFERS HAVING PASSIVATED CONTACTS

(71) Applicants: Alliance for Sustainable Energy, LLC, Golden, CO (US); Colorado School of Mines, Golden, CO (US); Università degli Studi di Padova, Padua (IT)

(72) Inventors: Pauls STRADINS, Golden, CO (US); David Levi YOUNG, Golden, CO (US); Kejun CHEN, Perrysburg, OH (US); Sumit AGARWAL, Arvada, CO (US); Enrico NAPOLITANI, Padua (IT); William Michael NEMETH, Wheat Ridge, CO (US)

(21) Appl. No.: 18/885,915

(22) Filed: Sep. 16, 2024

Related U.S. Application Data
(60) Provisional application No. 63/582,795, filed on Sep. 14, 2023.
(60) Provisional application No. 63/694,019, filed on Sep. 12, 2024.

(51) Int. Cl. H01L 31/18; H01L 31/0236

(52) U.S. Cl. CPC H10F 71/129; H10F 77/703

(57) ABSTRACT

The present disclosure relates to a wafer that includes a silicon core having a textured surface and a dielectric layer having a first thickness, where the textured surface includes a plurality of features where each feature is characterized by a first point and a second point separated by a distance, H, at least a portion of the features further include a solid channel positioned substantially at or near the first point, and the solid channel passes through at least a portion of the first thickness.

### CROSS-REFERENCE TO RELATED APPLICATIONS

This application claims priority from U.S. Provisional Patent Application Nos. 63/582,795 and 63/694,019 filed on Sep. 14, 2023 and Sep. 12, 2024, respectively, the contents of which are incorporated herein by reference in their entirety.

### CONTRACTUAL ORIGIN

This invention was made with government support under Contract No. DE-AC36-08GO28308 awarded by the Department of Energy. The government has certain rights in the invention.

### BACKGROUND

The next generation PV cells will likely be based on passivated contacts. Among other things, incumbent technologies face the difficulty that the passivation and carrier transport are coupled and cannot be independently changed (for example, thinning a tunneling SiO₂ layer can lead to better transport, but deteriorates the interface passivation). Introducing nanosized solid channels in passivating, dielectric layers may solve that problem. However, it is difficult to create solid channels of a given size and spacing on dielectric layers, especially on textured surfaces. Thus, there remains a need for methods that can address these problems to produce silicon wafers having controllable solid channel sizes, positions, and densities that, in turn, provide desirable physical properties and performance metrics.

### SUMMARY

An aspect of the present disclosure is a wafer that includes a silicon core having a textured surface and a dielectric layer having a first thickness, where the textured surface includes a plurality of features where each feature is characterized by a first point and a second point separated by a distance, H, at least a portion of the features further include a solid channel positioned substantially at or near the first point, and the solid channel passes through at least a portion of the first thickness. In some embodiments of the present disclosure, the wafer my further include a silicon layer having a second thickness, where the dielectric layer is positioned between the silicon core and the silicon layer, the silicon layer maintains the textured shape of the textured silicon core, and the solid channel passes through at least one of a portion of the first thickness or a portion of the second thickness or a combination thereof.

In some embodiments of the present disclosure, the solid channel may pass completely through each of the first thickness and the second thickness. In some embodiments of the present disclosure, the dielectric layer may include at least one of a silicon oxide, an aluminum oxide, or a silicon nitride, or a combination thereof. In some embodiments of the present disclosure, H may be between 100 nm and 10 μm. In some embodiments of the present disclosure, the feature may include at least one of a pyramid, a cone, a ridge, a circular bulge, an inverted pyramid, an inverted cone, a dimple, or a combination thereof. In some embodiments of the present disclosure, the pyramid may be characterized by a tip positioned at the first point, a trough positioned at the second point, at least three facets that meet to form the tip, and the solid channel is positioned substantially at or near the tip.

In some embodiments of the present disclosure, the silicon core may include at least one of a crystalline silicon or a poly-crystalline silicon or a combination thereof. In some embodiments of the present disclosure, the first thickness may be between 1.0 nm and 20 nm. In some embodiments of the present disclosure, the second thickness may be between 5 nm and 300 nm.

In some embodiments of the present disclosure, the solid channel may have a diameter of less than 1000 nm. In some embodiments of the present disclosure, the wafer may have a concentration of solid channels between 1×10⁴ solid channels/cm² and 1×10¹⁰ solid channels/cm². In some embodiments of the present disclosure, the wafer may further include a metal grid, where the silicon layer is positioned between the metal grid and the dielectric layer. In some embodiments of the present disclosure, the solid channel may be positioned under the metal grid. In some embodiments of the present disclosure, the wafer may further include a sheet resistance, Rₛ, between 576Ω/□ and 719Ω/□. In some embodiments of the present disclosure, the wafer may further include an implied open-circuit voltage, iVoc, between 672 mV and 716 mV.

An aspect of the present disclosure is a method that includes irradiating a wafer with a light, where the wafer includes a silicon core having a textured surface, a dielectric layer having a first thickness, and a silicon layer having a second thickness. Further, the dielectric layer is positioned between the silicon core and the silicon layer, the textured surface includes a plurality of features where each feature is characterized by a first point and a second point separated by a distance, H, and the silicon layer maintains the textured shape of the textured silicon core, and the irradiating creates a solid channel having a first diameter at the first point of at least a portion of the features. In some embodiments of the present disclosure, after the irradiating, the method may further include an etching of the wafer, where the etching increases a diameter of a solid channel.

In some embodiments of the present disclosure, the method may further include, before the irradiating, a pre-irradiating of the wafer with a second light, where the pre-irradiating selectively weakens or thins the dielectric layer.

### BRIEF DESCRIPTION OF DRAWINGS

Some embodiments are illustrated in referenced figures of the drawings. It is intended that the embodiments and figures disclosed herein are to be considered illustrative rather than limiting.

Not all drawings are drawn to scale.

FIG. 1 illustrates a schematic (not to scale) of a wafer having a textured surface (Panel A) and a scanning electron microscopy (SEM) image of a textured silicon surface (Panel B), according to some embodiments of the present disclosure.

FIG. 2 illustrates a method for producing a wafer having pinholes preferentially positioned at the high points, e.g., tips of pyramids, of a textured surface, according to some embodiments of the present disclosure.

FIG. 3 illustrates a schematic of treating a pyramid with laser light (Panel A—not drawn to scale) and a TEM image of an actual pyramid that was treated according to that method (Panel B), according to some embodiments of the present disclosure. Platinum (Pt) was used for the TEM measurement.

FIG. 4 illustrates schematics of test structures subjected to laser processing: (Panel A) Group 1: oxide sample; (Panel B) Group 2: n-type a-Si sample; (Panel C) Group 3: n-type poly-Si sample; and (Panel D) the varying laser processing conditions (each referred to as a “spot”) for a 4×7 grid on a 30 mm by 50 mm sample for evaluating irradiating conditions used for each spot for each Groups 1-3, according to some embodiments of the present disclosure. Each laser spot had a dimension of 5.1×5.1 mm². The first number in each spot represents the laser energy densities (ranging from 100 to 450 mJ/cm²). The second number indicates the number of laser pulses (ranging from 1 to 4).

FIG. 5 illustrates SEM images of textured silicon surfaces having pinholes positioned at the tips of pyramidal features, according to some embodiments of the present disclosure. SEM images for 200 nm n-type poly-Si sample (with 1.5 nm oxide) pre-poly-Si removal using tetramethyl ammonium hydroxide (TMAH) are shown in the top row Panels (A-C), and in the bottom row post-poly-Si removal using TMAH are shown in Panels (D-F). SEM images for the spot with no laser processing are shown in (Panel A) pre-TMAH (Panel D) post-TMAH. SEM images for spot 23 with 450 mJ/cm² and 4 pulses are shown in (Panel B) pre TMAH (Panel E) post TMAH. SEM images for spot 53 with 600 mJ/cm² and 4 pulses are shown in (Panel C) pre-TMAH (Panel F) post-TMAH.

FIGS. 6A and 6B illustrate SEM images for poly-Si samples (Group 3) pre-TMAH etching with varying laser energy densities and number of pulses and SEM images for poly-Si samples (Group 3) post-TMAH etching with varying laser energy densities and number of pulses, respectively, according to some embodiments of the present disclosure.

FIG. 7A, 7B, and 7C illustrate SEM images for a-Si samples (Group 2) pre-TMAH etching with varying laser energy densities and number of pulses, SEM images for a-Si samples (Group 2) post-TMAH etching with varying laser energy densities and number of pulses, and SEM images for SiOₓ samples pre-TMAH etching with varying laser energy densities and number of pulses, respectively, according to some embodiments of the present disclosure.

FIG. 8 illustrates photoluminescence (PL) images for (Panel A) a poly-Si sample, (Panel B) an a-Si sample, and (Panel C) an oxide sample after passivation with Al₂O₃ and FGA, according to some embodiments of the present disclosure. The PL exposure time was 1/30^{th} of a second.

FIG. 9 illustrates a UV laser system showing four mirrors to guide the beam and the position of the sample stage, where the system was utilized to form pinholes passing through silicon-containing structures as described herein, according to some embodiments of the present disclosure. The laser spots at mirror #1 and at the sample are shown in the lower righthand side.

FIG. 10 illustrates (Panel A) a schematic of an overlapping laser beam at ¼ expansion and 1 pulse (first row), ¼ expansion and 2 pulses (second row), and ½ expansion and 1 pulse (third row) and (Panel B) an image of a poly-Si sample after such laser processing, according to some embodiments of the present disclosure.

FIG. 11 illustrates SEM images of textured silicon surfaces that were exposed to laser induced melting (pre- and post-etching using TMAH, Panels A and B, respectively), according to some embodiments of the present disclosure.

### REFERENCE NUMERALS

100 . . . wafer
110 . . . silicon core
120 . . . dielectric layer
130 . . . silicon layer
140 . . . textured surface
150 . . . pyramid
155 . . . tip
157 . . . trough
160 . . . solid channel
200 . . . method
210 . . . irradiating
220 . . . etch in g
300 . . . irradiated tip

### DETAILED DESCRIPTION

The present disclosure relates to methods and silicon wafers resulting from such methods that address the problems described above. Among other things, the methods described herein include applying short duration laser pulses to textured and passivated silicon wafer surfaces to selectively modify the high points on textured silicon surfaces, such as pyramid tips. Specifically, irradiating a textured surface with light from a laser can preferentially heat the high points, resulting in the selective melting and solidifying of the mass near the high points, e.g., tips. This melting can result in the mass transfer of materials through a dielectric layer between an underlying core layer and overlying silicon layer, with the subsequent solidification of the melted material resulting in the formation of a channel of solid material passing through the dielectric layer, with the channel having desirable charge transport characteristics while maintaining sufficient passivation. The charge transport resulting from the formation of such solid channels enable the manufacture of novel passivated contacts, both of n- and/or p-type polarities, that can be produced by laser processing. Further, the laser processing methods described herein can be spatially selective and can be applied preferentially and selectively to specific targeted regions of a wafer, for example, under the front metal grid, and/or to the backside area of the cell.

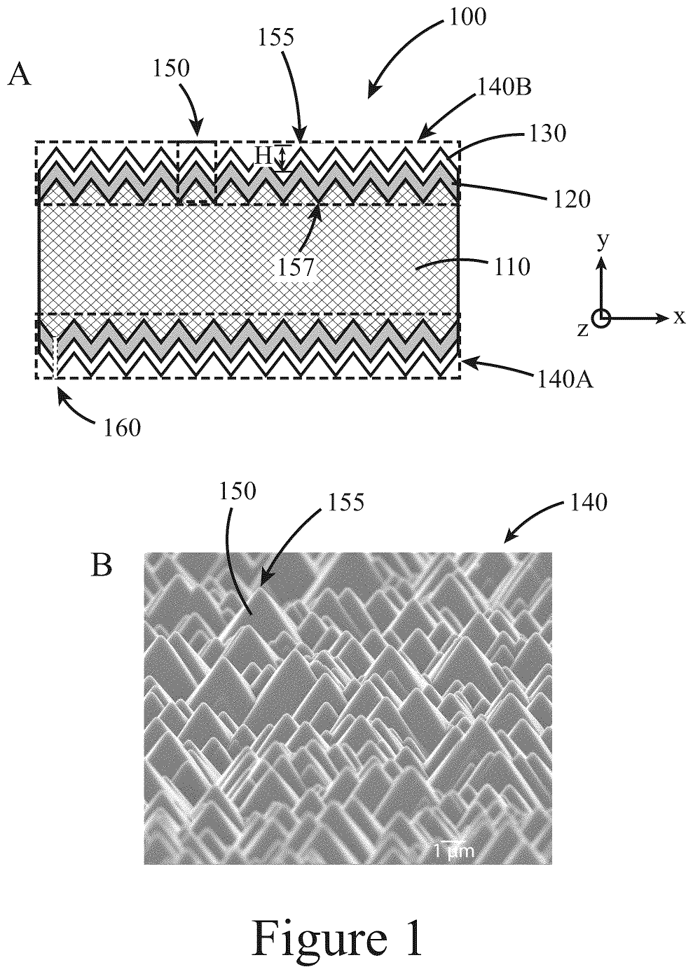

FIG. 1 illustrates a wafer 100, according to some embodiments of the present disclosure. The wafer 100 is constructed of a silicon core 110 having at least one textured surface 140. As shown in both Panels A and B of FIG. 1, a textured surface 140 may include a plurality of pyramid-shaped structures, referred to herein simply as pyramids 150. FIG. 1 illustrates a wafer having two textured surfaces (140A and 140B), with a silicon core 110 positioned between the two textured surfaces (140A and 140B). More specifically, a pyramid 150 may be characterized as a three-dimensional structure having a high point (i.e., a first point) in the y-dimension, a tip 155 in the case of a pyramid 150, and a low point (i.e., a second point) in the y-dimension, a trough 157, where H is the distance between the tip 155 and the trough 157 in the y-dimension. A pyramid 150 may be constructed of three, four, and/or more than four facets that converge from the troughs 157 to the tips 155.

Panel B of FIG. 1 illustrates an SEM image of a surface of a silicon wafer 100 having a textured surface 140 characterized by a plurality of pyramids 150, with a scale-bar indicating scale. In some embodiments of the present disclosure, H may be between 100 nm and 10 μm, or between 1 μm and 8 μm, or between 200 nm and 5 μm. Further, a pyramid 150 may be defined by three or four facets that meet to form a tip 155. However, a pyramid 150 is just one possible feature that may define a textured surface 140 of a silicon core 110. In some embodiments of the present disclosure, a textured surface 140 of a silicon core 110 may include at least one of a pyramid, a cone, a ridge, a circular bulge, an inverted pyramid, an inverted cone, a dimple, and/or other surfaces feature capable of focusing light into a wafer's surfaces. Each of these examples of features defining a textured surface may be characterized by high points and low points, such that, like with pyramids, irradiating the features may result in the preferential heating, melting, and solidifying of the high points.

Referring again to Panel A of FIG. 1, a silicon core 110 may be constructed using at least one of a single-crystalline silicon, a multi-crystalline silicon, and/or any other suitable silicon material. In some embodiments of the present disclosure, a silicon core 110 may have a thickness between 20 μm and 500 μm or between 50 μm and 150 μm. In some embodiments of the present disclosure, a silicon core 110 may be silicon manufactured by the Czochralski method, with such silicon abbreviated as Cz-Si. In some embodiments of the present disclosure, a silicon core 110 may be at least one of p-doped or n-doped or a combination thereof. For example, a silicon core 110 may have a first side and/or first portion that is substantially p-dope and a second side and/or second portion that is substantially n-doped.

Referring again to Panel A of FIG. 1, the exemplary wafer 100 further includes a dielectric layer 120 positioned adjacent to and in physical contact with the silicon core 110. In some embodiments of the present disclosure, a dielectric layer 120 may be constructed of at least one of a transparent conducting oxide, a silicon carbide, a silicon oxide, an aluminum oxide, and/or a silicon nitride. In some embodiments of the present disclosure, a wafer 100 may include two or more dielectric layers 120, with each dielectric layer positioned adjacent to a neighboring dielectric layer. In some embodiments of the present disclosure, a dielectric layer 120 may be characterized by a thickness that is between 1.0 nm and 200 nm, or between 1.0 nm and 10 nm, or between 1.1 nm to 2.5 nm, or less than 2 nm. In some embodiments of the present disclosure, a wafer 100 may include two or more dielectric layers, where each dielectric layer has a thickness that is between 1.0 nm and 20 nm, or between 1.0 nm and 10 nm, or between 1.1 nm to 2.5 nm, or less than 2 nm. As shown in Panel A of FIG. 1, a dielectric layer 120 may retain the shape and/or features of the underlying silicon core 110, thereby maintaining the same textured surface 140, e.g., a plurality of pyramids 150.

Referring again to Panel A of FIG. 1, a wafer 100 may further include a silicon layer 130 such that a dielectric layer 120 is positioned between a silicon core 110 and the silicon layer 130. In some embodiments of the present disclosure, a silicon layer 130 may be constructed of at least one of a polycrystalline silicon or an amorphous silicon or a combination thereof. A silicon layer 130 may have a thickness that is between 5 nm and 300 nm or between 20 nm and 100 nm. Further, a silicon layer 130 may maintain the textured shape of the underlying textured surface 140 of the silicon core 110 and/or the underlying textured surface 140 of the dielectric layer 120. Thus, a silicon layer 130 may have a textured surface 140, e.g., a textured surface 140 having a plurality of pyramid-shaped features and/or other surface features capable of focusing light, with examples provided above. Thus, as indicated by the dashed box around the pyramid 150 illustrated in Panel A of FIG. 1, a pyramid 150 may include material from each of a silicon layer 130, a dielectric layer 120, and a silicon core 130. Further, in some embodiments of the present disclosure, a silicon layer 130 may be constructed of a material that is at least one of intrinsic, p-doped, n-doped, or a combination thereof.

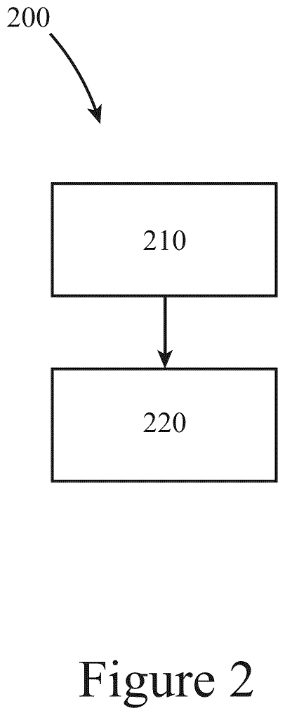

Referring again to Panel A of FIG. 1, a wafer 100 made according to the methods described herein (see FIG. 2) may be further characterized by a solid channel 160 that may be preferentially positioned substantially at or near a high point (i.e., first point) of a feature defining a textured surface 140, e.g., near or at the tip 155 of a pyramid 150. A single example of a solid channel 160 is illustrated, located at the tip 155 of a pyramid 150 on the lower textured surface 140A. However, a textured surface 140 may have a plurality of solid channels 160 distributed at or near the tips 155 of a plurality of pyramids 150. The solid channel 160 is illustrated as a dashed box to indicate that, in this example, the solid channel passes through the silicon layer 130 and the dielectric layer 120 and enters the underlying silicon core 110. This illustration suggests that a solid channel 160 is an empty space or volume. This is typically not the case, with an exception being after a wafer 100 is treated using a chemical etching and/or mechanical etching step, as described in more detail below. Among other things, such etching may assist with the visualization of where solid channels 160 are positioned, by the physical removal of at least a portion of the solid material making up the solid channels 160 such that they become visible by microscopy methods. Such portions of a solid channel 160, portions that have been removed by mechanical and/or chemical etching, are referred to herein as “etch pits”.

A solid channel 160 may result from the irradiating of a textured surface 140 with a laser light, because of the melting of at least one of a silicon layer 130, a dielectric layer 120, and/or the underlying silicon core 110 of a pyramid 150. During the melting of the materials making up these features, mass may be transferred (e.g., by diffusion) between the silicon layer 130 and the silicon core 110, through the dielectric layer 120. For example, poly-Si from a silicon layer 130 may be transferred into and through a dielectric layer 120 into an underlying silicon core 110 and/or Cz-Si from a silicon core 110 may be transferred into and through a dielectric layer 120 into an overlying silicon layer 130. Once the heating of the textured surface 140 stops due to the cessation of irradiating with laser light, the melted materials, now in a mixed state, solidify. Among other things, the mixing of these materials enables and/or enhances charge transport between the silicon core 110 and the silicon layer 130. Further, this process results in a solid channel 160 that is not an empty space or volume. Instead, a solid channel 160 resulting from the irradiating step is a channel filled with a silicon material having a composition that is different from the starting features and final surrounding materials, e.g., the silicon layer 130 and/or the silicon core 110.

Such a solid channel 160 may be characterized, as shown herein, to provide both good charge transport and passivation.

Referring again to Panel A of FIG. 1, a solid channel 160 positioned substantially at or near a high point (i.e., first point) of a feature defining a textured surface 140A, e.g., near or at the tip 155 of a pyramid 150, may pass through at least one of a portion of the thickness of a silicon layer 130 and/or through at least a portion of the thickness of a dielectric layer 120, thereby providing a pathway for charge transfer to and/or from the silicon core 110. In some embodiments of the present disclosure, a solid channel 160 may pass completely through each of the thickness of a silicon layer 130 and the thickness of one or more dielectric layers 120.

In some embodiments of the present disclosure, a solid channel 160, may have a diameter at or near the tip, in the xz-plane, of less than 1000 nm, or less than 100 nm, or less than 10 nm, or less than 1 nm. In some embodiments of the present disclosure, a solid channel 160 may have a diameter between 2 nm and 500 nm or between 10 nm and 100 nm. In some embodiments of the present disclosure, a wafer 100 may be characterized by a concentration of solid channels 160 on a textured surface 140 that is between 1×10⁴ solid channels/cm² and 1×10¹⁰ solid channels/cm² or between 1×10⁵ solid channels/cm² and 1×10⁸ solid channels/cm² (as measured in the xz-plane). In some embodiments of the present disclosure, a wafer 100 having a plurality of solid channels 160 passing through a textured surface 140 of the wafer 100 may be characterized by a contact resistivity between 0.1 mohms-cm² and 300 mohms-cm², or 0.1 between mohm-cm² and 30 mohm-cm², or between 0.1 mohm-cm² and 10 mohm-cm².

FIG. 2 illustrates a method 200 for making a wafer 100 like that illustrated in FIG. 1, a wafer 100 having a plurality of solid channels 160 passing through at least a portion of at least one of a silicon layer 130 and a dielectric layer 120, according to some embodiments of the present disclosure. This exemplary method 200, includes at least one irradiating 210 step and an optional treating 220 step. In summary, as described above, irradiating 210 using laser light results in the preferential melting and solidifying of at least a portion of the high points of the features, e.g., the tips 155 of pyramidal features, defining a wafer's textured surface 140, resulting in, among other things, the forming of solid channels 160 having good charge transport and passivation properties. Thus, the melting and solidifying resulting from the irradiating 210 modify the structure and morphology of these high points (e.g., tips), as described above, resulting in the forming of solid channels 160 that pass through the thicknesses of at least one of the dielectric layer 120 and/or the silicon layer 130, and that may penetrate into the underlying silicon core 110.

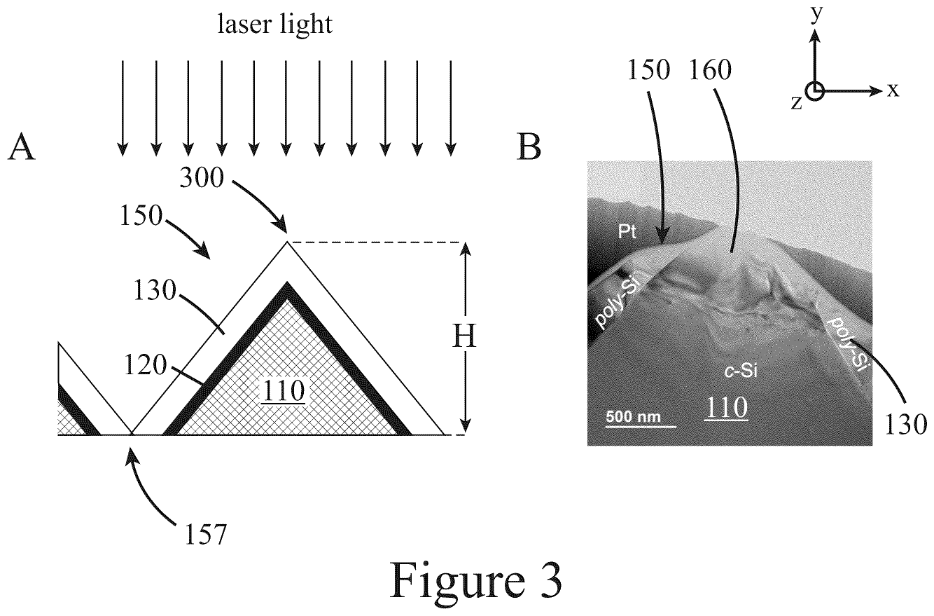

This process is illustrated schematically in Panel A of FIG. 3, with reference numeral 300 indicating an irradiated tip of a pyramid 150 that has undergone melting and solidifying of at least a portion of the tip (not drawn to scale). As indicated by the parallel lines representing laser light in Panel A of FIG. 3, the entire outer surface of a pyramid 150 is irradiated with laser light and, as a result, the entire outer surface of the pyramid 150 is heated. However, the tips 155 of pyramids 150 are preferentially heated, relative to the other portions facets/sides of the pyramids 150, for example portions of the facets/sides positioned closer to the troughs 157.

Panel B of FIG. 3 illustrates an SEM image of a tip 155 of a pyramid 150 that was modified by melting and solidifying resulting from irradiating 410 the tip with laser light. A solid channel 160 is clearly visible, passing through apoly-Si silicon layer 130, into the underlying c-Si silicon core 110. The dielectric layer is not visible in this image. The SEM image illustrates that, in some embodiments of the present disclosure, a solid channel 160 passing through at least one of a silicon layer 130 and/or a dielectric layer 120, may have an irregular shape, unlike the simplified representation of a solid channel 160 illustrated in Panel A of FIG. 1. For example, a solid channel 160 may have a starting diameter in the xz-plane that gradually broadens as one moves from the tip to the trough in the z-axis direction. Thus, a solid channel 160 may have a cross-sectional shape, in the xy-plane, that is approximately the same as the surface feature itself; e.g., a pyramid 150 may be characterized by a solid channel also having a pyramidal shape. Referring again to Panel B of FIG. 3, a solid channel 160 may penetrate from the tip 160 of a pyramid 150 to a depth of between greater than 0 nm and less than or equal to 1000 nm.

Referring again to FIG. 2, in some embodiments of the present disclosure, a method 200 may include an etching 220 step, to enable the visualization and characterization of the solid channels 160 produced during the irradiating 210 step; e.g., to enable quantification of solid channel concentrations, etc. An “etch pit” is not visible in Panel B of FIG. 3 as the molten/solidified material making up the solid channel 160 has not been removed by etching 220. However, treating a wafer 100 treated with a tetramethyl ammonium hydroxide (TMAH) etching 220 step was sometimes utilized in the experimental work described below to enable more precise quantification of the success and/or failure of different irradiating conditions for accomplishing sufficient melting/solidifying to enable the formation of solid channels 160 that balances the creating of desirable charge transport without excessive deterioration of passivation. Thus, in some embodiments of the present disclosure, etching 220 may modify the solid channels 160 formed during the irradiating 410 by removing material in a solid channel 160. In some embodiments of the present disclosure, etching 220 may include at least one of a chemical etching step and/or a mechanical etching step. In some embodiments of the present disclosure, etching 220 may be performed using a chemical etchant, for example TMAH and/or KOH. Etching 220 may be performed at room temperature or at an elevated temperature.

Referring again to FIG. 2, in some embodiments of the present disclosure, a light used for irradiating 210 a textured surface 140 for forming solid channels 160 may include a laser light having a wavelength between 200 nm and 400 nm. In some embodiments of the present disclosure, irradiating 210 may include exposing a textured surface 140 to pulsed laser light. In some embodiments of the present disclosure, the irradiating 210 for forming solid channels 160 may include exposing a textured surface 140 of a wafer 100 to between 1 and 10 pulses of laser light. In some embodiments of the present disclosure, a pulse of light may be for a period of time between 1 fs and 100 ns, or between 100 fs and 100 ns, or between 1 ns and 100 ns. In some embodiments of the present disclosure, a time interval between pulses may be between 1 fs and 1 second. In some embodiments of the present disclosure, a total energy provided to a textured surface 140 of a wafer 100 by all of the one or more pulses of a light source combined, e.g., laser light pulses, may be between 1 mJ/cm² and 10,000 mJ/cm², or between 500 mJ/cm² and 5000 mJ/cm², or between 100 mJ/cm² and 200 mJ/cm². In some embodiments of the present disclosure, a laser light may be provided to a textured surface 140 of a wafer 100 by exposing the textured surface 140 to a circular spot of laser light having an area between 10-6 mm² to 10⁶ mm², or between 0.001 mm² and 100 mm², or between 0.1 mm² and 100 mm². Typically, the solidifying of material melted by laser irradiation takes longer than the laser pulse, but within a similar time scale. For example, for a pulse duration of about 20 ns, the solidification may take between 10 ns to 100 ns to fully occur.

In some embodiments of the present disclosure, a method may include two irradiating steps, where each step utilizes a different laser configured to achieve different outcomes. As described above, a laser supplying light having a wavelength between 200 nm and 400 nm may be utilized to preferentially melt the materials located at and/or near the tips 155 of pyramids 150, resulting in the formation of solid channels 160 having desirable charge transport and passivation characteristics. In some embodiments of the present disclosure, a method may begin with an optional step of irradiating a wafer 100 having a silicon core 110, a dielectric layer 120, and a silicon layer 130 as described above. However, in this optional step, the irradiating may be performed using laser light having a different wavelength range, that preferentially degrades the dielectric layer 120, resulting in the thinning and/or partial removal of a portion of the dielectric layer positioned near the tip of a pyramid. This preferential thinning and/or removal of the dielectric layer 120 may, among other things, result in lower intensity requirements, less irradiating time, fewer pulses, and/or lower energy requirements for the subsequent irradiating 210 step for the forming of solid channels 160. Further, the preferential thinning and/or removal of a dielectric layer 120 may result in the improved mass transfer of material through the thinned region of the dielectric layer 120 between a silicon core 110 and a silicon layer 130 during the laser treating that preferentially melts/solidifies material near pyramid tips. In some embodiments of the present disclosure, a laser for selectively degrading a dielectric layer 120, for example, in a wafer 100 having an overlying silicon layer 130, may include a CO₂ laser producing light having a wavelength between 9.3 μm and 10.6 μm, inclusively. This wavelength of light is absorbed by silicon oxide dielectric layers 120 and is not absorbed by poly-Si layers, i.e., silicon layers 130.

To summarize, the present disclosure describes a new process to locally and selectively create solid channels 160 in the oxide and/or silicon textured surfaces of wafers 100 by pulsed laser melting followed by solidification of the melted material. As shown below, in some embodiments of the present disclosure, nanosecond laser pulses can selectively modify the tips 155 of pyramids 150 randomly distributed on textured surfaces 140. In some embodiments of the present disclosure, the resulting solid channels 160 may be modified by subsequent processing steps, e.g., using a chemical etchant, to enable visualization of the initial solid channels 160 formed during the irradiating step. In some embodiments of the present disclosure, an optional irradiating step using a laser producing light having a wavelength between 9.3 μm and 10.6 μm may be performed to preferentially weaken or thin a dielectric layer 120, before irradiating with a laser to form solid channels 160.

The laser treating methods described herein have four significant advantages of other methods for producing passivated contacts: 1) The processing can be done entirely at room temperature, which avoids the complexity of high thermal steps; 2) The areal density of the solid channels can be precisely controlled by changing the laser energy density and number of pulses; 3) Laser processes are spatially selective and can be applied to specific targeted regions of the wafers or cells (for example, to under the front metal grid, or to some fraction of the backside area of the cell); and 4) Laser processes are highly favored in industry due to the short processing time, reduced maintenance, and more cost-effective production. Thus, the methods described herein, enable the fabrication of novel nano-solid-channel-based passivating contacts, which can be applied to both n-type and p-type contacts.

### Experimental:

Double-sided textured (˜180 μm) phosphorus-doped, 3-5 Ω·cm resistivity, Czochralski silicon (Cz-Si) wafers (e.g., monocrystalline wafers) were cleaned with piranha and standard RCA methods. Thus, the silicon cores 110 of these wafers 100 were constructed of Cz-Si. For the purposes of these experiments, a low temperature SiOₓ dielectric layer 120 was formed on both sides of the wafer 100 with each side having a thickness of about 1.5 nm, followed by the growth of an intrinsic polycrystalline silicon (poly-Si) layer, i.e. silicon layer 130, having a thickness of about 200 nm via low-pressure chemical vapor deposition.

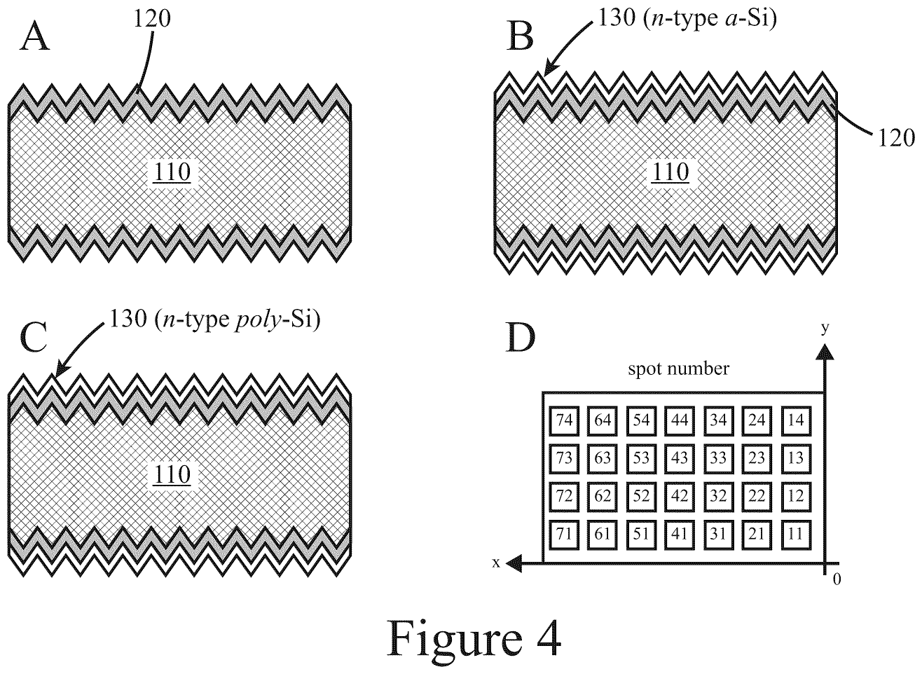

Wafer 100 samples having SiOₓ dielectric layers 120 with thicknesses of ˜2.3 nm were produced using bare n-type Cz wafers (e.g., the silicon core 110 of these wafers 100 were constructed of n-type Cz-Si), and a thermal oxidation at 800° C. for 9 minutes and 30 seconds was performed after the cleaning method to form the SiOₓ dielectric layer 120. These samples were then split into three groups. The first group of samples (Group 1) was irradiated with KrF laser light having a wavelength of 248 nm “as is” (also hereinafter referred to as “oxide samples”, see Panel A of FIG. 4). The second group of samples (Group 2) were coated with intrinsic a-Si having a thickness of about 50 nm, which was then doped to form a silicon layer of n-type a-Si:H. Group 2 was subjected to similar irradiation processes as in Group 1. The original a-Si layer was deposited via plasma-enhanced chemical vapor deposition (PECVD) (also referred to herein as “a-Si samples”, see Panel B of FIG. 4). Group 3 was also subjected to the same process as Group 2 to form a silicon layer of n-type a-Si:H, but then further processed by converting the a-Si:H layer to a crystallized poly-Si layer by heat treating at 850° C. for 30 minutes (also referred to herein as “poly-Si samples”, see Panel C of FIG. 4). This heating step also resulted in dopant diffusion from the n-type Cz-Si core 110 into the poly-Si silicon layer 130. Then Group 3 was subjected to similar irradiation processes as in Groups 2 and 3. (Solid channels 160 are not illustrated in any of Panels A-C of FIG. 4.)

The poly-Si samples, Group 3, went through a passivation step that included the atomic layer deposition (ALD) of a dielectric layer of Al₂O₃ and 60 minutes of thermal annealing at 400° C. in Forming gas (mixture of 10% hydrogen and 90% nitrogen gases), so called Forming Gas Anneal (FGA). Afterwards, the Al₂O₃ layer was removed in a 1% aqueous HF solution before annealed by pulsed laser melting (PLM) with a KrF laser. Note that the Al₂O₃ layer was initially deposited because it contains H, which can passivate the sample after the FGA step. After the FGA step, H is transferred into the Si stack to passivate defects, after which the Al₂O₃ layer is no longer needed and is, therefore, removed to allow direct access of the poly-Si layer to the PLM.

Panel D of FIG. 4 illustrates the laser pattern used on a 30×50 mm wafer sample. The laser conditions were varied with the laser energy density (increasing horizontally) and the number of laser pulses (increasing vertically). The numbers within each laser spot (indicated as a square) represent each laser condition tested. The laser energy density ranged between 125 mJ/cm² and 450 mJ/cm² for the poly-Si samples (Group 3), between 100 mJ/cm² and 425 mJ/cm² for the a-Si samples (Group 2), and between 150 mJ/cm² and 475 mJ/cm² for the SiOₓ samples (Group 1). The number of pulses was varied between 1 and 4 pulses. The energy density was chosen based on the surface morphology of the samples, which was analyzed using SEM.

The solid channels in the oxide layer of the Group 1 samples were treated using a chemical etchant of 15% w/w tetramethyl ammonium hydroxide (TMAH) to selectively etch the poly-Si (e.g., the silicon layer 130) at 50° C. for 10 minutes after immersion in 1% hydrofluoric acid (HF) to remove the surface oxide, which occurs naturally on an Si surface exposed to air and therefore should be removed by HF. Due to the higher etching effects of TMAH on Si (e.g., the silicon layer 130) relative to the SiOₓ (the dielectric layer 120), the poly-Si (or a-Si) silicon layer 130 etched faster than the oxide dielectric layer 120, and the reaction slowed drastically when the TMAH reached the oxide interface. However, in areas with solid channels, the TMAH solution etched the underlying c-Si (e.g., the silicon core 110) creating open spaces in the solid channels, including in the silicon core 110, referred to herein as “etch pits”, while the intact oxide layer prevented TMAH from etching the c-Si and those areas lack etch pits. Note the area of the etch pits of the c-Si depends on the various parameters of the etching solution (e.g., solution strength, temperature, and time of the reaction) and, thus, it is not representative of the size of the solid channels created during the laser treating step.

Surface morphology: As described previously, irradiating a textured surface with laser light results in a higher heat flux absorbed locally at the tips of the pyramids relative to other areas of the pyramids (such as the faces or the valleys). For a given laser energy density, the heat flux to a textured surface is lower by ˜√3 because of the higher surface area of compared to a planar surface. However, at the pyramid tips, there exist four melt fronts from surfaces or planes that converge to form a tip, but with very limited heat dissipation into the bulk c-Si of the silicon core 110 (see Panel A of FIG. 3). This results in local heating and melting at a much larger length scale compared to a planar surface. Panel B of FIG. 3 illustrates a cross-sectional TEM image of one pyramid after laser processing. The structural changes in the resultant solid channel 160, resulting from laser irradiating, can be visualized by the melted and solidified c-Si of the silicon core 110 nearest the tip of the pyramid 150.

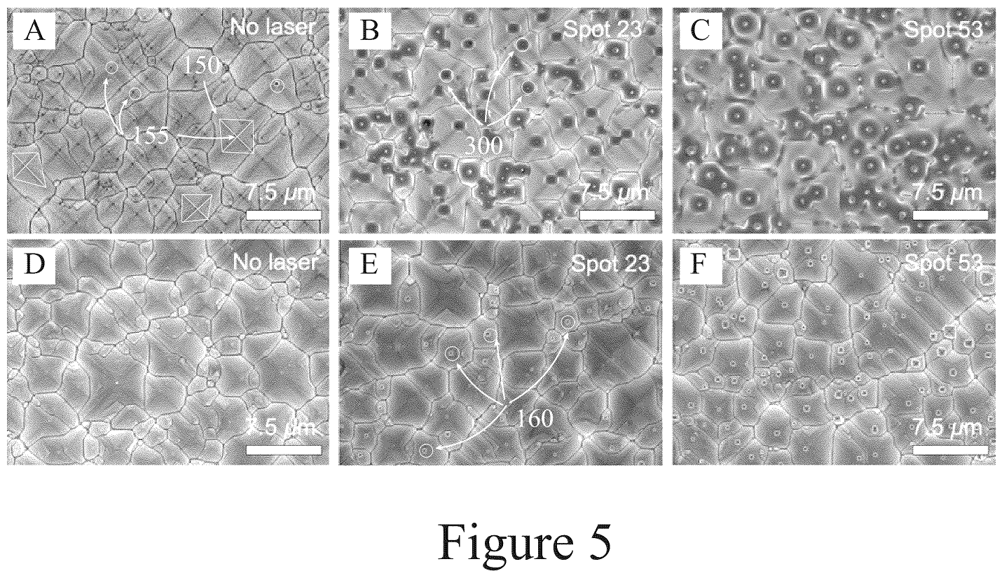

To determine the laser processing conditions best suited for producing a passivated contact, a range of different laser energy densities and number of pulses was studied (as shown in Panel D of FIG. 4). FIG. 5 illustrates planar SEM images of wafers treated with two selected laser conditions and one wafer without laser processing before and after a TMAH treating step to remove the poly-Si layer (i.e., silicon layer 130). The melting behavior of a poly-Si silicon layer 130 can be seen in Panels B and C of FIG. 5, with the positions of some irradiated tips 300 indicated. Spot 23 and 53 resulted from laser energy densities of 450 mJ/cm², with 4 pulses, and 600 mJ/cm², with 4 pulses, respectively. The higher energy laser condition resulted in a higher degree of melting of the poly-Si layer (e.g., silicon layer 130). After the removal of the poly-Si layer by TMAH, the location of solid channels can be seen in Panels E and F of FIG. 5. As expected, the tips of the pyramids have etched inward in the form of “inverted pyramids”, indicating the locations where the poly-Si layer and the SiOₓ layer have melted forming a solid channel 160 that passes through both the silicon layer 130 and the dielectric layer 120. Spot 53 resulted in a higher density of “inverted pyramids” compared to spot 23, which shows that more solid channels 160 were created with higher laser energy density and the same number (4) of pulses.

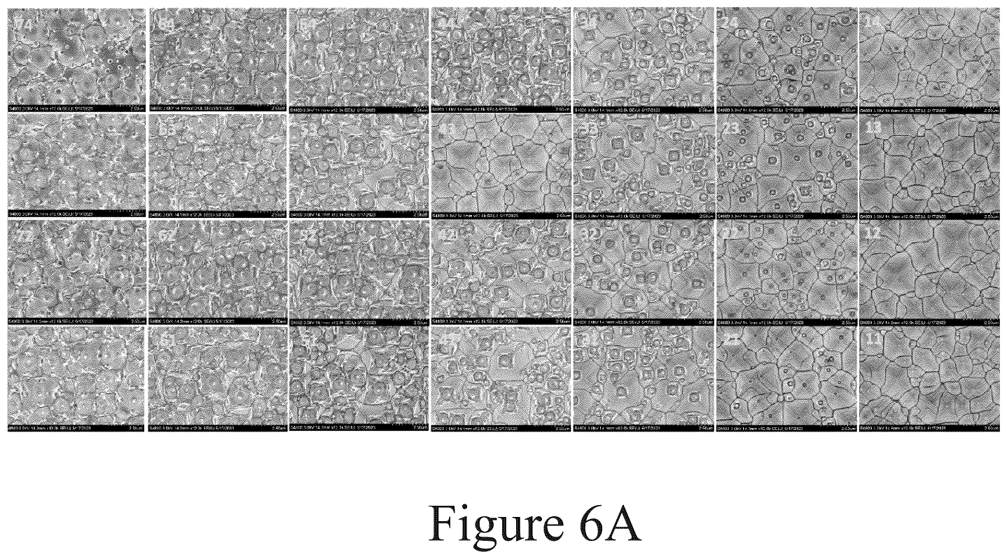

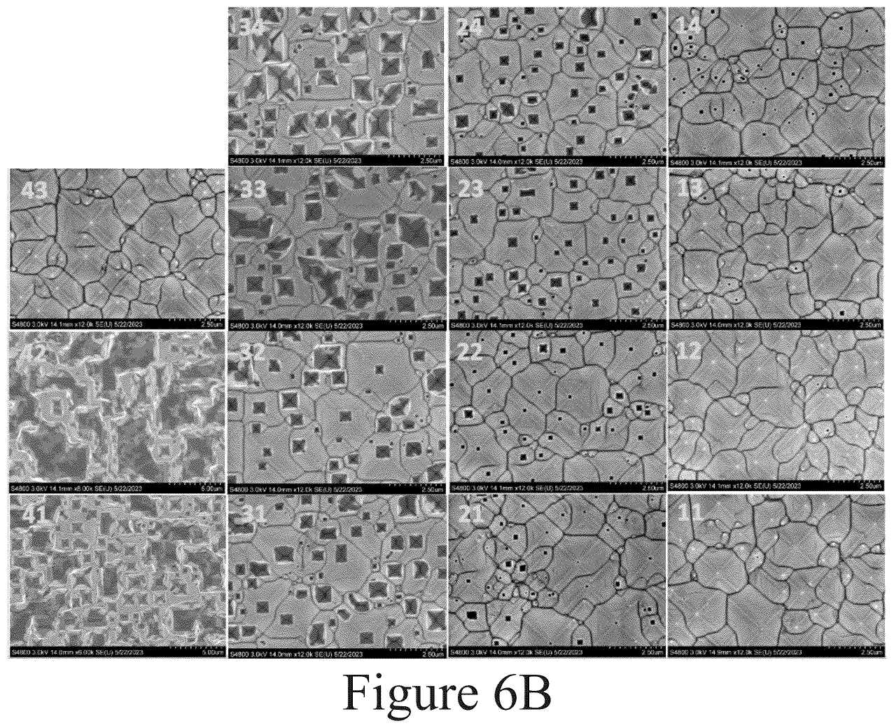

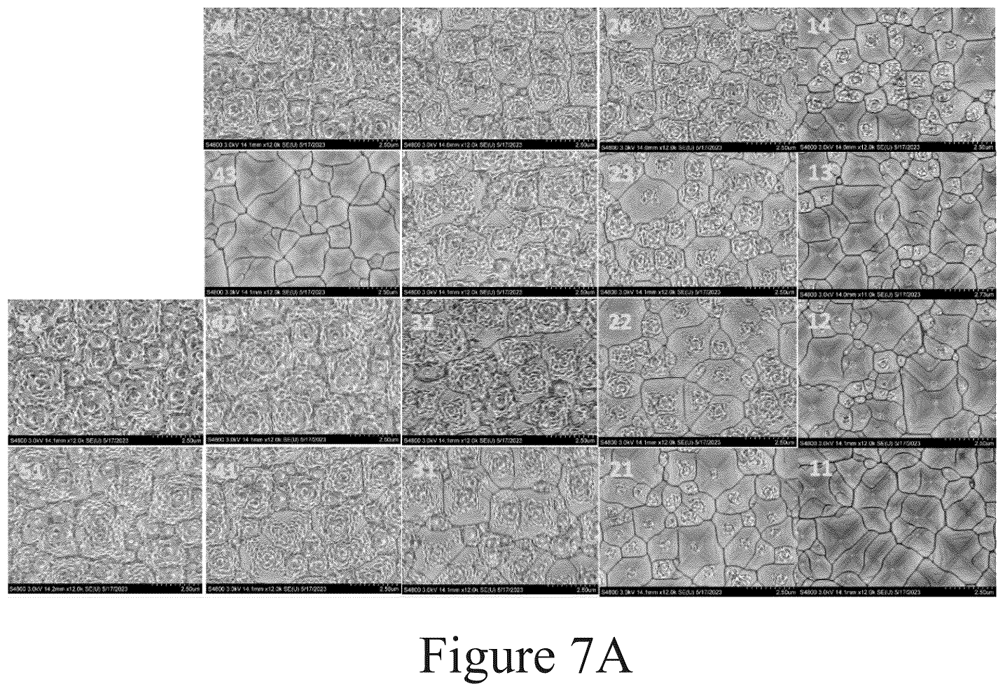

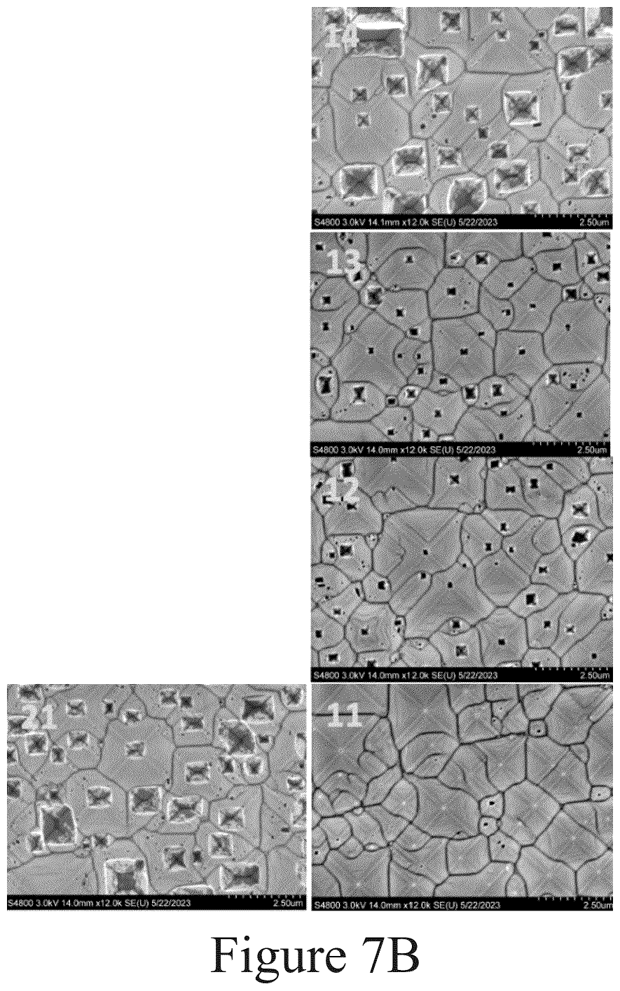

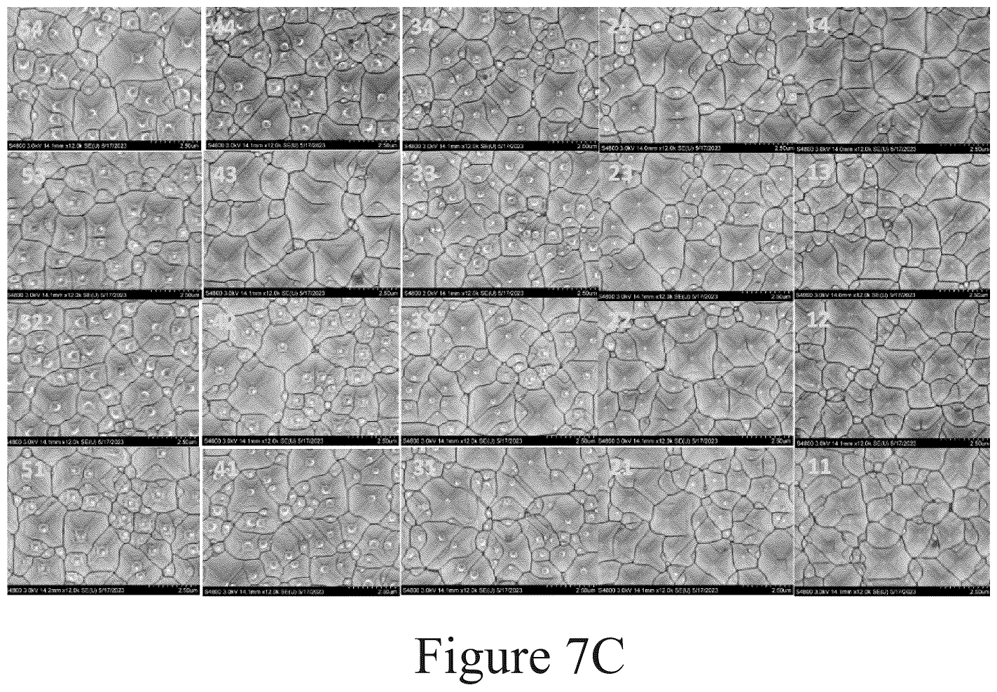

It is interesting to note that solid channels 160 formed at the tips 155 of smaller pyramids 150 in greater numbers compared to those at larger pyramids 150. This could not be explained by the larger surface area of the larger pyramids, because the heat flux at the tips of the pyramids should be the same for both small and large pyramids. A hypothesis for this observation is that the higher degree of melting at the smaller pyramids may result from the reflection of laser light from nearby larger pyramids to the smaller pyramids. This may lead to a higher local heat flux at the smaller pyramids compared to larger pyramids. SEM images of laser spots before and after removal of the poly-Si layer (Group 3) (e.g., the silicon layer 130) are illustrated in FIGS. 6A and 6B. SEM images for a-Si (Group 2) and SiOₓ (Group 1) are illustrated in FIG. 7A, 7B, and 7C. Again, as specified previously, the removing of both the silicon layer 130 and the dielectric layer 120 occurs preferentially at the tips of the pyramids, whereas the bulk of these layers located below the tips remain substantially intact.

Next, the solid channel areal densities, after etching with TMAH, resulting from the different laser conditions were calculated using a free, open-source software tool (DotDotGoose). It is clear from these data that increasing the laser energy density and number of pulses can increase the solid channel areal density from 2.8×10⁵ solid channels/cm⁻² (spot 11) to 1.7×10⁷ solid channels/cm⁻² (spot 74). This range of solid channel density is promising because the optimal areal density of solid channels that can result in low contact resistivity is between 10⁶ solid channels/cm⁻² and 10⁸ solid channels/cm⁻². The solid channel areal density started to “saturate” after spot 64 in one SEM image (area of 7.08×10⁻⁶ cm²) because almost all of the pyramid tips melted, resulting in etch pits.

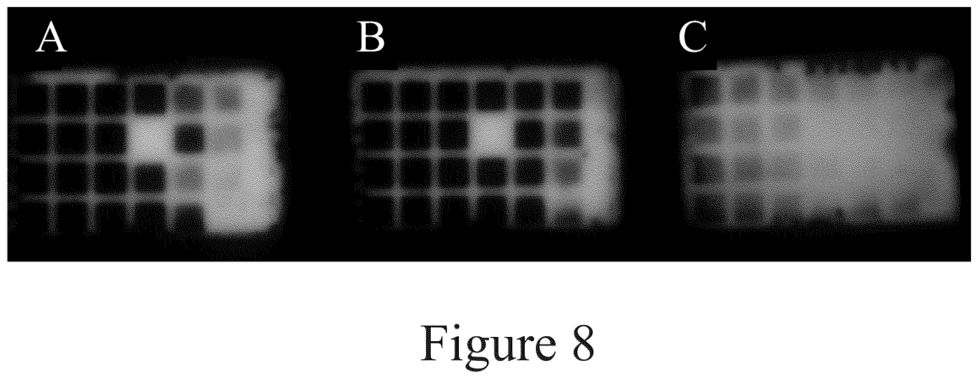

Passivating contact performance: To demonstrate the performance of a laser-processed contact for passivating contacts purpose, two important parameters where considered. The first parameters is passivation, which can be determined using photoluminescence (PL), while the second one is transport properties. PL images were taken after the passivation step of Al₂O₃ and FGA. Panels A, B, and C of FIG. 8 illustrate PL images taken at an exposure time of 1/30 of a second for poly-Si samples (Group 3), a-Si samples (Group 2), and the oxide samples (Group 1). The intensity of PL decreased as the laser energy density and the number of pulses increased for all three samples. Spot 43 was intentionally not exposed to laser light. for comparison purposes. This spot appears bright in PL, which indicates that the samples were processed correctly and there was no contamination during the process and passivation is good. To ensure the passivation quality, laser spots with bright PL are desirable because bright PL indicates that the dielectric layer 120 (e.g., oxide layer) has sufficient solid channels for charge transfer to occur, but not to an extent that the passivating affects are degraded. For the poly-Si sample (Group 3) (see Panel A of FIG. 8), a low laser energy density range between 125 mJ/cm² and 200 mJ/cm² with 1 and 4 pulses resulted in brighter PL intensity than others. For the a-Si sample (Group 2) (see Panel B of FIG. 8), the range was between 100 mJ/cm² and 125 mJ/cm² and a much larger range between 150 mJ/cm² and 325 mJ/cm² may be selected for the oxide samples (Group 1) (see Panel C of FIG. 8).

The laser process described herein has numerous advantages, including that of being spatially selective. That is, one can scan a sufficiently narrow laser beam over a cell and create a solid channel only in select locations. For example, one can selectively form solid channels only under the metal grid of a cell. This has significant technological advantages. In some embodiments of the present disclosure, a metal grid may include a plurality of metal strips with each having a width between 50 μm and 100 μm. A metal grid may be constructed of any suitable conductive metal including gold, silver, copper, aluminum, and/or molybdenum.

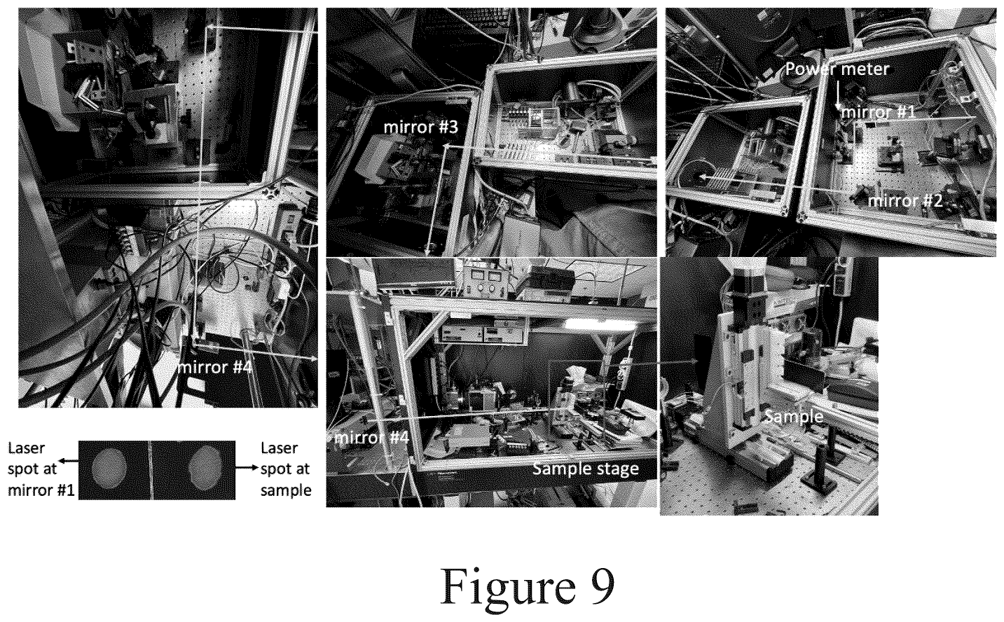

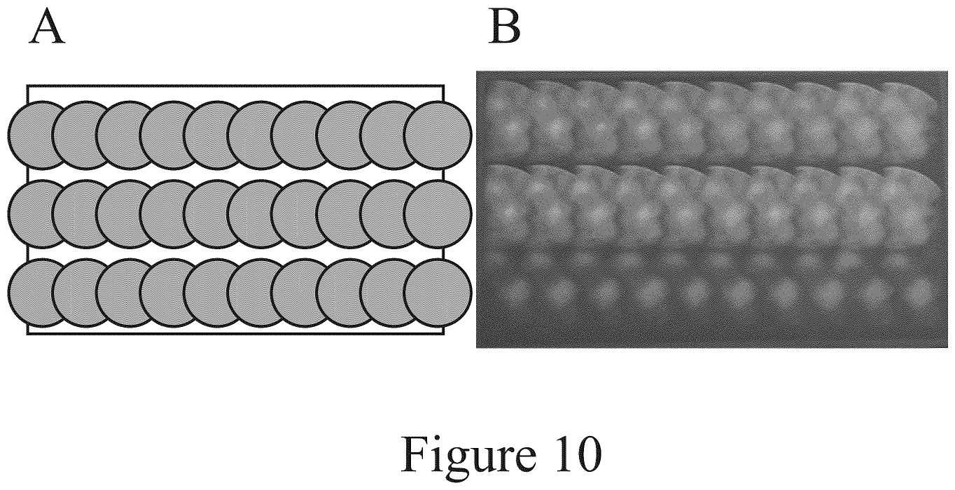

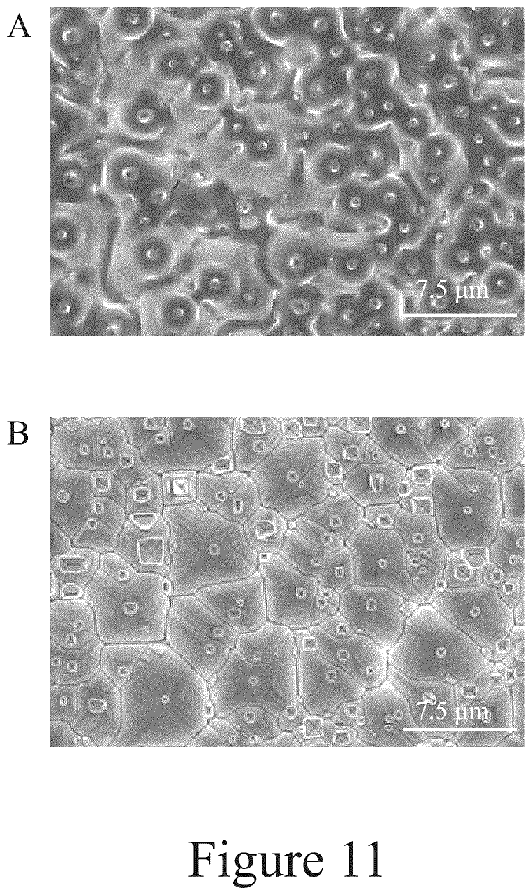

Laser capabilities: A laser was developed utilizing a high power 355 nm laser with a spot size of 0.38 cm² (beam diameter of 7 mm). The goal was to be able to reliably reproduce the laser melting conditions and resultant behaviors. To set up the laser system, beam alignments with multiple refraction at UV-coated mirrors were needed to guide the beam through multiple enclosures to the x-y sample stage (see setup in FIG. 9). A power meter was used to measure the beam power at the inlet of the laser and at the sample stage. The sample was mounted vertically with a clamp stand. The x-y stage can be controlled within mm through the LabView program. The two laser spots in the lefthand corner show that the shape of the laser beam stayed constant at the mirror #1 towards the beginning of the laser beam and at the end of the beam path near the sample stage. Laser energy densities between 75 mJ and 190 mJ were tested, with pulses between 1 pulse and 8 pulses. The SEM images (see FIGS. 10 and 11) show that the range of laser power tested was largely too strong for the purposes of these experiments because the surface of silicon experienced intense melting and the pyramidal structures were not recognizable after exposure to the laser light. However, when operating the laser power at the lower limit of about 75 mJ, the beam started to become non-uniform with areas of more intense laser power and areas with less intense power (see the top and bottom images at 75 mJ). The areas with more laser power at 75 mJ only melted the tips of the pyramids, as desired.

To make the beam more uniform, experiments were conducted with a “light pipe”, which is a hexagonal shaped fused silica rod with a diameter of 8 mm. This approach results in the beam entering the light pipe at an angle and is focused by internally reflecting the beam, resulting in a more uniform beam exiting the light pipe. However, these attempts were not successful in homogenizing the beam due to the close diameter of the light pipe to the beam diameter. This caused some light to spill over when entering the light pipe. Alternatively, a beam could be made divergent using a quartz or MgF₂ lens of ˜5 cm focal length.

To make the beam more uniform, a 355 nm UV beam expander was tested to utilize the part of the beam that has the stronger power. Panel A of FIG. 10 shows the schematic of overlapping laser beam spots at ¼ expansion, 1 pulse (top row); ¼ expansion, 2 pulses (middle row); and ½ expansion, 1 pulse (bottom row). Panel B of FIG. 10 illustrates the poly-Si sample after laser processing. The addition of the beam expander was successful in making the beam larger, and simultaneously reduced the beam power. However, there were still areas of higher beam power than others. The beam appeared non-uniform even after the beam expander. FIG. 11 illustrates SEM images of the sample described for FIG. 10 before and after TMAH etching step.

The passivation and charge transport properties of the three groups described above (Group 1 “oxide-only”, Group 2 “a-Si:H”, and Group 3 “poly-Si”) were measured using photoluminescence and transfer length method (TLM) measurements at three different laser energy densities; high, medium, and low (high is between 600 mJ/cm² and 1200 mJ/cm²; medium is between 400 mJ/cm² and 700 mJ/cm²; and low is between 200 mJ/cm² and 500 mJ/cm². The results are summarized below in Table 1, where pc is contact resistivity, Rₛ is sheet resistance, and iVoc is the implied open-circuit voltage.

TABLE 1
Passivated Contacts' Performance Metrics

| Sample | Energy | ρ_{c} | Rₛ | iVoc |
|---|---|---|---|---|
| Type | Density | [mΩcm²] | [Ω/□] | [mV] |
| Oxide-only | low | — | — | 670 |
| | medium | 5.1 | 9.3 | 668 |
| | high | 1.1 | 12 | 663 |
| a-Si:H | low | — | — | 650 |
| | medium | — | — | 659 |
| | high | — | — | 700 |
| poly-Si | low | — | — | 716 |
| | medium | 0.17 | 576 | 696 |
| | high | 0.01 | 719 | 672 |

ρ_{c} and Rₛ indicate charge transport and a ρ_{c} value below 5 mohm-cm² and a Rₛ value below 20 ohm/sq is typically good. iVoc indicates passivation quality and a value between 680-720 mV is good, with higher values desirable.

### Examples

Example 1. A wafer comprising: a silicon core comprising a textured surface; and a dielectric layer comprising a first thickness, wherein: the textured surface comprises a plurality of features where each feature is characterized by a first point and a second point separated by a distance, H, at least a portion of the features further comprise a solid channel positioned substantially at or near the first point, and the solid channel passes through at least a portion of the first thickness.

Example 2. The wafer of Example 1, further comprising a silicon layer comprising a second thickness, wherein: the dielectric layer is positioned between the silicon core and the silicon layer, the silicon layer maintains the textured shape of the textured silicon core, and the solid channel passes through at least one of a portion of the first thickness or a portion of the second thickness or a combination thereof.

Example 3. The wafer of either Example 1 or Example 2, wherein the solid channel passes completely through each of the first thickness and the second thickness.

Example 4. The wafer of any one of Examples 1-3, wherein the dielectric layer comprises at least one of a silicon oxide, an aluminum oxide, or a silicon nitride, or a combination thereof.

Example 5. The wafer of any one of Examples 1-4, wherein the wafer comprises two or more dielectric layers.

Example 6. The wafer of any one of Examples 1-5, wherein H is between 100 nm and m or between 1 μm and 8 μm or between 200 nm and 5 km.

Example 7. The wafer of any one of Examples 1-6, wherein the feature is configured to focus light.

Example 8. The wafer of any one of Examples 1-7, wherein the feature comprises at least one of a pyramid, a cone, a ridge, a circular bulge, an inverted pyramid, an inverted cone, a dimple, or a combination thereof.

Example 9. The wafer of any one of Examples 1-8, wherein the pyramid is characterized by: a tip positioned at the first point, a trough positioned at the second point, at least three facets that meet to form the tip, and the solid channel is positioned substantially at or near the tip.

Example 10. The wafer of any one of Examples 1-9, wherein the silicon core comprises at least one of a crystalline silicon or a multi-crystalline silicon or a combination thereof.

Example 11. The wafer of any one of Examples 1-10, wherein the silicon core comprises a third thickness between 20 μm and 500 μm or between 50 μm and 150 μm.

Example 12. The wafer of any one of Examples 1-11, wherein the first thickness is between 1.0 nm and 20 nm or between 1.0 nm and 10 nm or between 1.1 nm to 2.5 nm or less than 2 nm.

Example 13. The wafer of any one of Examples 1-12, wherein each dielectric layer has a thickness between 1.0 nm and 10 nm or between 1.1 nm to 2.5 nm or less than 2 nm.

Example 14. The wafer of any one of Examples 1-13, wherein the silicon layer comprises at least one of a polycrystalline silicon, a silicon carbide, an amorphous silicon, a transparent conducting oxide, a silicon oxide, a doped silicon oxide, or a combination thereof.

Example 15. The wafer of any one of Examples 1-14, wherein the second thickness is between 5 nm and 300 nm or between 20 nm and 100 nm.

Example 16. The wafer of any one of Examples 1-15, wherein the solid channel has a diameter of less than 1000 nm, or less than 100 nm, or less than 10 nm, or less than 1 nm.

Example 17. The wafer of any one of Examples 1-16, wherein the solid channel has a diameter between 2 nm and 500 nm or between 10 nm and 100 nm.

Example 18. The wafer of any one of Examples 1-17, wherein a concentration of solid channels is between 1×10⁴ solid channels/cm² and 1×10¹⁰ solid channels/cm² or between 1×10⁵ solid channels/cm² and 1×10⁸ solid channels/cm².

Example 19. The wafer of any one of Examples 1-18, comprising a contact resistivity between 0.1 mohms-cm² and 300 mohms-cm² or 0.1 between mohm-cm² and 30 mohm-cm² or between 0.1 between mohm-cm² and 10 mohm-cm².

Example 20. The wafer of any one of Examples 1-19, further comprising a metal grid, wherein the silicon layer is positioned between the metal grid and the dielectric layer.

Example 21. The wafer of any one of Examples 1-20, wherein the solid channel is positioned under the metal grid.

Example 22. The wafer of any one of Examples 1-21, wherein the metal grid is constructed using at least one of gold, silver, copper, aluminum, molybdenum, or a combination thereof.

Example 23. The wafer of any one of Examples 1-22, further comprising a contact resistivity, ρ_{c}, between 0.01 mΩcm² and 0.17 mΩcm².

Example 24. The wafer of any one of Examples 1-23, further comprising a sheet resistance, Rₛ, between 576Ω/□ and 719 Ω/□.

Example 25. The wafer of any one of Examples 1-24, further comprising an implied open-circuit voltage, iVoc, between 672 mV and 716 mV.

Example 26. The wafer of any one of Examples 1-25, further comprising an etch pit positioned within the silicon core near or substantially near the first point.

Example 27. A method comprising: irradiating a wafer with a light, wherein: the wafer comprises: a silicon core comprising a textured surface; a dielectric layer comprising a first thickness; a silicon layer comprising a second thickness; the dielectric layer is positioned between the silicon core and the silicon layer; the textured surface comprises a plurality of features where each feature is characterized by a first point and a second point separated by a distance, H, and the silicon layer maintains the textured shape of the textured silicon core; and the irradiating creates a solid channel having a first diameter at the first point of at least a portion of the features.

Example 28. The method of Example 27, wherein the light is a laser light.

Example 29. The method of either Example 27 or Example 28, wherein the laser light has a wavelength between 200 nm and 400 nm.

Example 30. The method of any one of Examples 27-29, wherein the irradiating is performed by pulsing the laser light.

Example 31. The method of any one of Examples 27-30, wherein the pulsing comprises between 1 and 10 pulses of light.

Example 32. The method of any one of Examples 27-31, wherein each pulse of light is for a period of time between 1 fs and 100 ns or 100 fs and 100 ns or between 1 ns and 100 ns.

Example 33. The method of any one of Examples 27-32, wherein the irradiating provides a total energy between 1 mJ/cm² and 10,000 mJ/cm² or between 500 mJ/cm² and 5000 mJ/cm² or between 100 mJ/cm² and 200 mJ/cm².

Example 34. The method of any one of Examples 27-33, wherein the laser light is provided to the wafer during the exposing at a circular spot having an area between 10-6 mm² to 106 mm² or between 0.001 mm² and 100 mm² or between 0.1 mm² and 100 mm².

Example 35. The method of any one of Examples 27-34, further comprising, after the irradiating, an etching of the wafer, wherein the etching increases a diameter of a solid channel.

Example 36. The method of any one of Examples 27-35, wherein the etching performed using at least one of a chemical etchant or a mechanical etchant.

Example 37. The method of any one of Examples 27-36, wherein the etching comprises a first step of exposing the wafer to hydrofluoric acid and a second step of exposing the wafer to tetramethyl ammonium hydroxide (TMAH).

Example 38. The method of any one of Examples 27-37, further comprising, before the irradiating, a pre-irradiating of the wafer with a second light, wherein in the pre-irradiating selectively weakens or thins the dielectric layer.

Example 39. The method of any one of Examples 27-38, the second light is a laser light.

Example 40. The method of any one of Examples 27-39, wherein the light of the second laser light has a wavelength between 9.3 μm and 10.6 μm.

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A wafer comprising:
a silicon core comprising a textured surface; and
a dielectric layer comprising a first thickness, wherein:
the textured surface comprises a plurality of features where each feature is characterized by a first point and a second point separated by a distance, H,
at least a portion of the features further comprise a solid channel positioned substantially at or near the first point, and
the solid channel passes through at least a portion of the first thickness.

2. The wafer of claim 1, further comprising a silicon layer comprising a second thickness, wherein:
the dielectric layer is positioned between the silicon core and the silicon layer,
the silicon layer maintains the textured shape of the textured silicon core, and
the solid channel passes through at least one of a portion of the first thickness or a portion of the second thickness or a combination thereof.

3. The wafer of claim 2, wherein the solid channel passes completely through each of the first thickness and the second thickness.

4. The wafer of claim 1, wherein the dielectric layer comprises at least one of a silicon oxide, an aluminum oxide, or a silicon nitride, or a combination thereof.

5. The wafer of claim 1, wherein H is between 100 nm and 10 μm.

6. The wafer of claim 1, wherein the feature comprises at least one of a pyramid, a cone, a ridge, a circular bulge, an inverted pyramid, an inverted cone, a dimple, or a combination thereof.

7. The wafer of claim 6, wherein the pyramid is characterized by:
a tip positioned at the first point,
a trough positioned at the second point,
at least three facets that meet to form the tip, and
the solid channel is positioned substantially at or near the tip.

8. The wafer of claim 1, wherein the silicon core comprises at least one of a crystalline silicon or a multi-crystalline silicon or a combination thereof.

9. The wafer of claim 1, wherein the first thickness is between 1.0 nm and 20 nm.

10. The wafer of claim 1, wherein the second thickness is between 5 nm and 300 nm.

11. The wafer of claim 1, wherein the solid channel has a diameter of less than 1000 nm

12. The wafer of claim 1, further comprising a concentration of solid channels between 1×10⁴ solid channels/cm² and 1×10¹⁰ solid channels/cm².

13. The wafer of claim 2, further comprising a metal grid, wherein the silicon layer is positioned between the metal grid and the dielectric layer.

14. The wafer of claim 13, wherein the solid channel is positioned under the metal grid.

15. The wafer of claim 2, further comprising a sheet resistance, Rₛ, between 576Ω/□ and 719 Ω/□.

16. The wafer of claim 2, further comprising an implied open-circuit voltage, iVoc, between 672 mV and 716 mV.

17. A method comprising:
irradiating a wafer with a light, wherein:
the wafer comprises:
a silicon core comprising a textured surface;
a dielectric layer comprising a first thickness; and
a silicon layer comprising a second thickness, wherein;
the dielectric layer is positioned between the silicon core and the silicon layer;
the textured surface comprises a plurality of features where each feature is characterized by a first point and a second point separated by a distance, H, and the silicon layer maintains the textured shape of the textured silicon core; and
the irradiating creates a solid channel having a first diameter at the first point of at least a portion of the features.

18. The method of claim 17, further comprising, after the irradiating, an etching of the wafer, wherein the etching increases a diameter of a solid channel.

19. The method of claim 17, further comprising, before the irradiating, a pre-irradiating of the wafer with a second light, wherein in the pre-irradiating selectively weakens or thins the dielectric layer.
